(19) United States
(12) Patent Application Publication
(10) Pub. No.: US 2004/0038544 A1
(43) Pub. Date: Feb. 26, 2004

(54) Method for processing a semiconductor wafer using double-side polishing

(75) Inventors: Guoqiang (David) Zhang, Ballwin, MO (US); Henry Frank Erk, St.Louis, MO (US); Tracy M. Ragan, Warrenton, MO (US); Julie A. Kearns, Winfield, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/420,557

(22) Filed: Apr. 22, 2003

Related U.S. Application Data
(63) Continuation-in-part of application No. 09/633,532, filed on Aug. 7, 2000, now abandoned.

(51) Int. Cl. H01L 21/302; H01L 21/461

(52) U.S. Cl. 438/709; 438/689

(57) ABSTRACT

A method for polishing front and back surfaces of a semiconductor wafer includes the step of providing a polishing apparatus having a wafer carrier generally disposed between a first polishing pad and a second polishing pad. The first pad has a hardness significantly greater than a hardness of the second pad. The wafer is placed in the wafer carrier so that the front surface faces the first pad and so that the back surface faces the second pad. A polishing slurry is applied to at least one of the pads and the carrier, first pad and second pad are rotated. The front surface is brought into contact with the first pad and the back surface is brought into contact with the second pad for polishing the front and back surfaces of the wafer whereby less wafer material is removed from the back surface engaged by the second pad and the back surface has less gloss than the front surface after polishing so that the front surface and back surface are visually distinguishable.

### CROSS-REFERENCE TO RELATED APPLICATION

This application is a continuation-in-part of U.S. patent application Ser. No. 09/633,532 filed Aug. 7, 2000, which is incorporated herein by reference.

### BACKGROUND OF THE INVENTION

The present invention relates generally to methods of processing semiconductor wafers, and more particularly, to an economical method of processing semiconductor wafers including simultaneously polishing front and back surfaces of the semiconductor wafers for producing flat wafers exhibiting low nanotopography and having visually distinguishable front and back surfaces.

Semiconductor wafers are generally prepared from a single crystal ingot, such as a silicon ingot, which is trimmed and ground to have one or more flats for proper orientation of the wafer in subsequent procedures. The ingot is then sliced into individual wafers which are each subjected to a number of processing operations to reduce the thickness of the wafer, remove damage caused by the slicing operation, and to create a highly reflective front side. A lapping operation (an abrasive slurry process) is typically performed on the front and back sides of the wafer to reduce the thickness of the wafer and remove damage induced by the slicing operation. A chemical etching operation using acid or caustic etchant may also be performed to reduce the thickness and remove damage after lapping. It is known that using an acid chemical etchant may negatively affect the nanotopography of the wafer.

Thereafter, one or both surfaces of each wafer are usually polished to remove damage to the front and back sides induced by prior operations and to ensure that the wafer is planar. Simultaneous double side polishing has become preferred in the industry because such polishing yields a wafer with flatter, more parallel sides. However, there are drawbacks to simultaneous double side polishing. For example, simultaneous double side polishing is more costly than single side polishing, and after such double side polishing, significant damage remains in the wafer surfaces. Moreover, the surfaces of the wafer may not be visually distinguishable, which may cause problems for certain machines used in down-stream processing of the wafer.

It is known to overcome the latter problem by dulling the back side by single side etching. Single side etching, however, negatively affects the nanotopography of the back side, which may effect the front side in a later front side polishing operation where the wafer is wax mounted. Most single side etching operations also negatively affect the edge of the wafer and/or the front side of the wafer, which is undesirable. Instead of a dulling operation, it is known to use a method of double side polishing whereby the rotational speed of the polishing pad and wafer carrier is manipulated to reduce the wafer material removed from the back side and thus make the back side distinguishable from the front side. It has been found that control of the amount of wafer material removed from each side of the wafer is less precise with manipulation of the rotational speed. Such loss of removal control causes an undesirable variation in the back side roughness and gloss. Moreover, the differential between the amount of wafer material removed from the front and back sides is relatively low.

### SUMMARY OF THE INVENTION

Among the several objects and features of the present invention may be noted the provision of a method of simultaneously polishing front and back surfaces of a semiconductor wafer that produces a relatively flat wafer; the provision of such a method which produces a wafer having visually distinguishable front and back sides; and the provision of such a method which removes substantially more wafer material from one of said front and back surfaces.

Briefly, a method of the present invention is directed to simultaneously polishing front and back surfaces of a semiconductor wafer. The method comprises providing a polishing apparatus having a wafer carrier generally disposed between a first polishing pad and a second polishing pad. The first pad has a hardness significantly greater than a hardness of the second pad. The wafer is placed in the wafer carrier so that the front surface faces the first pad and so that the back surface faces the second pad. A polishing slurry is applied to at least one of the pads and the carrier, first pad and second pad are rotated. The front surface is brought into contact with the first pad and the back surface is brought into contact with the second pad for polishing the front and back surfaces of the wafer whereby less wafer material is removed from the back surface engaged by the second pad and the back surface has less gloss than the front surface after polishing so that the front surface and back surface are visually distinguishable. The front surface of the wafer is finish polished to reduce haze and roughness therein. The front surface thereafter has a higher gloss than the back surface so that the front surface and back surface are visually distinguishable.

In another aspect of the invention, a method of processing a semiconductor wafer sliced from a single-crystal ingot and having front and back surfaces comprises the step of lapping the front and back surfaces of the wafer to reduce the thickness of the wafer and to improve the flatness of the wafer. The lapping step creates damage on the front and back surfaces. The front and back surfaces of the wafer are etched to reduce the damage on the front surface remaining after the lapping step. The front and back surfaces of the wafer are simultaneously polished to improve the flatness of the wafer and to reduce wafer damage on the front and back surfaces. The wafer damage remaining on the back surface is greater than the wafer damage on the front surface after completion of the simultaneous polishing step so that the back surface is visually distinguishable from the front surface. The front surface of the wafer is finish polished to reduce haze and roughness in the front surface. The front surface thereafter has a higher gloss than the back surface. The method is free of any step performed on the back surface which is not also performed on the front surface.

Other objects and features of the present invention will be in part apparent and in part pointed out hereinafter.

### BRIEF DESCRIPTION OF THE DRAWINGS

FIG. 1 is a schematic perspective view of a double side polishing apparatus used in a method of this invention; and

FIG. 2 is a flow diagram of a method of the present invention for processing a semiconductor wafer.

Corresponding reference characters indicate corresponding parts throughout the several views of the drawings.

### DETAILED DESCRIPTION OF THE PREFERRED EMBODIMENT

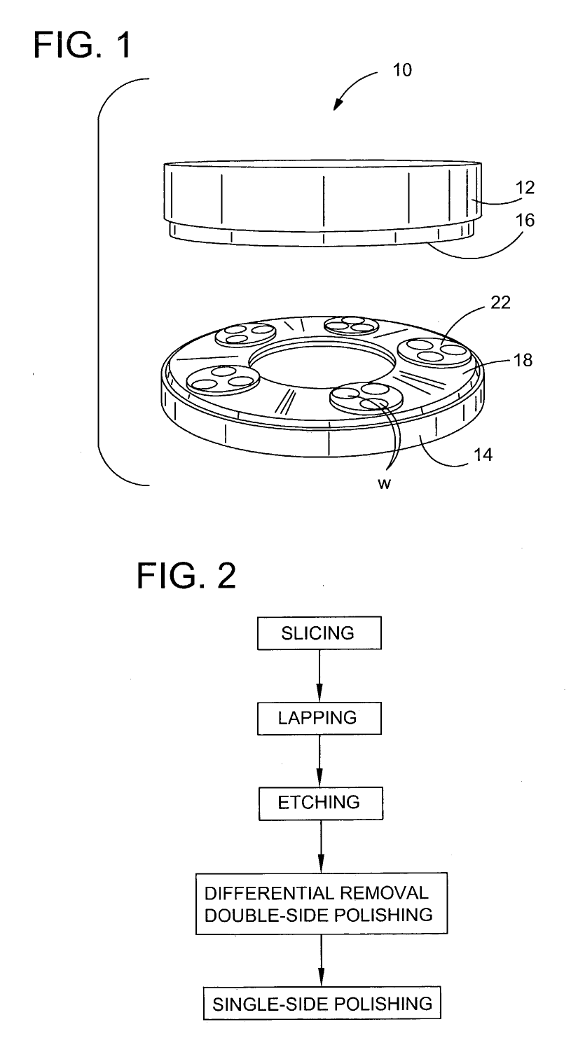

Referring now to the drawings and in particular to FIG. 1, a portion of a conventional double side polishing apparatus, such as a Model AC1200 or AC1400 made by Peter Wolters Gmbh, Rendsburg, Germany, is shown schematically and generally referred to as 10. The double side polisher is used to polish the front and back sides of semiconductor wafers W sliced from one or more monocrystalline silicon ingots. It is contemplated that other types of double side polishing apparatus may be used. The apparatus includes a generally annular upper platen 12 and a generally annular lower platen 14. An upper polishing pad 16 is mounted on the downwardly facing surface of the upper platen 12 and a lower polishing pad 18 is mounted on the upwardly facing surface of the lower platen 14.

The upper platen 12 and lower platen 14 are rotated at a selected rotation speed by suitable drive mechanisms (not shown), as is well known in the art. As will be described hereinafter with respect to a preferred method of this invention, the apparatus 10 includes a controller that allows the operator to select a rotation speed for the upper platen 12 that is different than the selected speed for the lower platen 14. Also, the platens are rotatable in different directions so that the platens may rotate in the same direction or in opposite directions.

A plurality of generally circular wafer carriers 22 are mounted on the lower polishing pad 18. Each wafer carrier 22 has at least one circular opening (three in this embodiment) which receives a wafer W to be polished. The periphery of each wafer carrier 22 has a ring gear (not shown) engaged by a “sun” or inner gear and an outer gear (not shown) of the apparatus 10. The inner and outer gears are driven by suitable drive mechanisms to rotate the carrier at a selected speed.

In a method of this invention, the wafer carriers 22 are mounted on the lower polishing pad 18 so that the carriers are generally disposed between the lower polishing pad and the upper polishing pad 16. At least one of the wafers W is placed in one of the openings in the wafer carrier 22 so that the front side faces the lower polishing pad 18 and the back side faces the upper polishing pad 16.

A conventional polishing slurry is applied to at least one of the pads. The wafer carrier 22, the upper pad 16 and the lower pad 18 are rotated. The upper platen 12 is lowered downward toward the lower platen 14 to bring the upper pad 16 into contact with the back side of the wafer W and to bring the lower pad 18 into contact with the front side of the wafer. The upper platen 12 is forced downward during polishing at a selected “down force” so that the back and front sides are polished simultaneously by the upper and lower pads, respectively. The lower pad 18, which polishes the front side, has a roughness significantly greater than a roughness of the upper pad 16. Preferably, the lower pad 18 is a rough (or “stock removal”) polishing pad made of polyurethane impregnated polyester felt material, preferably a Model Suba H2 pad, manufactured by Rodel Corporation, Newark, Del. The upper pad 16 is preferably a “finish” polishing pad made of poromeric polyurethane material, preferably a Model UR-100 pad manufactured by Rodel, which is significantly more porous than that of the rough pad. The lower pad has a compressibility of between about 6% and 8% and more preferably about 7%. The upper pad has a compressibility of between about 8% and 20%, and more preferably between about 10% and 12%. The lower pad 18 has a hardness significantly greater than the upper pad 16. For example, a Suba 80 pad, which is a finish pad comparable to a Model UR-100, has a Shore A hardness of about 13-20 using test method RM-02A-7-91, and the Suba H2 pad has a Shore A hardness of about 84 using the same test method. The lower pad 18 removes wafer material at a faster rate than the upper pad (removal rate ratio), preferably at least about five times more wafer material per rotation of the lower pad than the upper pad 16. More preferably, the removal rate ratio is about 10:1, and even more preferably is about 15:1. This double side polishing operation is performed for a relatively short period, preferably about 10 minutes or less, more preferably about 5 minutes. A relatively small amount of wafer material is removed from the back side, e.g., less than about 3 microns of wafer material and preferably less than about 2 microns. The wafer W is thereby polished using the rough pad and the finish pad such that less wafer material is removed from the back side than the front side and so that the back side has less gloss and a higher roughness than the front side. Accordingly, the front side is visually distinguishable from the back side.

The removal rate ratio and the difference between the wafer material removed from the front side and from the back side may be further increased by manipulating the relative rotational speed of the carrier 22, the upper platen 12 and upper pad 16, and the lower platen 14 and lower pad 18. Specifically, the upper platen 12 is rotated in the same direction as the wafer carrier 22 and at about the same speed as the wafer carrier. In this manner, relative motion between the upper pad 16 and each wafer W is decreased so that less material removal occurs during polishing. Table 1 includes suitable ranges and preferred parameters for the speed of the upper and lower platens 12, 14 and the inner and outer ring gears (the speed of the ring gears determines the speed of the carrier 22). Table 1 also includes a suitable range of polishing down force and a preferred polishing down force.

TABLE 1

| Parameters | Preferred | Suitable Range |
|---|---|---|
| Polishing Down Force, daN | 300 | 100-600 |
| Upper Platen Speed, RPM | 3 | 2-10 |
| Lower Platen Speed, RPM | −26¹ | −10-−40 |
| Inner Pin Ring Speed, RPM | −5 | 0-−10 |
| Outer Pin Ring Speed, RPM | 3 | 0-10 |

¹Negative sign for rotation indicates counter-clockwise direction, positive number indicates clockwise direction.

The removal rate ratio and the difference between the wafer material removed from the front side and from the back side may be further increased by increasing the temperature of the lower pad 18 in contact with the front side relative to the temperature of the upper pad 16 in contact with the back side. The temperature of each polishing pad is controlled by circulating water which is in thermal communication with the respective platens in contact with the pads. The AC1400 and AC2000 model polishers include a control system for controlling the temperature of the circulating water in communication with the upper platen 12 and a separate control system for the circulating water in communication with the lower platen 14. The separate systems enable the user to increase the temperature of the lower pad 18 with respect to that of the upper pad 16 and thereby remove more material from the front surface than the back surface.

In another method of the invention, semiconductor wafer W is placed in a conventional lapping apparatus (not shown) and is lapped to reduce the thickness of the wafer and to improve the flatness of the wafer. Reduction of the thickness via the lapping operation also removes damage caused by the wafer slicing operation. The lapping step, however, creates damage (lapping signature damage) on the front and back surfaces that has different characteristics than the damage caused by the wafer slicing operation. Suitable lapping apparatus include Peter Wolters Model Nos. AC1400 and AC2000, manufactured by Peter Wolters Corporation, Rendsburg, Germany. The lapping apparatus may be the same apparatus as the double-side polishing apparatus. The lapping operation removes a predetermined thickness of wafer material, such as about 40 to 100 microns, and preferably about 70 microns is removed by the lapping operation. The operation of the conventional lapping apparatus will be apparent to those skilled in the art and therefore will not be further described.

The front and back sides of the wafer W are etched to reduce the damage on the front side remaining after the lapping step. Preferably, the etchant used is a caustic (alkaline) etch because caustic etching is less harmful to the nanotopography of the wafer W than acid etchant. The wafers are preferably immersion etched, though other etching operations are contemplated. The wafer W may be edge polished after the etching step.

The front and back sides are simultaneously polished to improve the flatness of the wafer W and to reduce wafer damage on the front and back surfaces. The wafer damage remaining on the back surface is greater than the wafer damage on the front surface after completion of the simultaneous polishing step. Thus, the front side has a higher gloss and less roughness than the back surface so that the front and back sides are visually distinguishable. The simultaneous polishing step is preferably performed using the method described above so that significantly less wafer material is removed from the back side than the front side of the wafer W. More specifically, a harder, rougher pad is used to polish the front side than is used to polish the back side. In this method, it is preferable not to manipulate the rotational speed of the carrier 22 in order to increase the wafer removal differential between the front and back sides. Manipulation of the rotational speed may decrease the control over back side material removal, which will lead to an undesirable variation in the back side roughness and gloss.

The front side of the wafer is finish polished to reduce haze and roughness in the front side. It is believed that the nanotopography of the back side will be sufficiently uniform after the simultaneous polishing method of this invention so that the nanotopography of the back side will not negatively affect the nanotopography of the front side during front side polishing. The nanotopography of the front and back sides after simultaneous polishing is preferably less than 20 nm PV in a 2 mm×2 mm site and less than 70 nm PV on a 10 mm×10 mm site. More preferably, the nanotopography is less than 10 nm PV in a 2 mm×2 mm site, and even more preferably is substantially zero. After front side polishing, the front side has a higher gloss than the back surface so that the front and back sides are visually distinguishable and are distinguishable by sensors used to process the finished wafer. For example, the gloss on the front side is about 370 gloss units (g.u.) using a Mirror-Tri-Gloss Meter, made by Gardner, Inc., Germany, while the gloss on the back side is about 120 using the same meter. Moreover, the front side has a higher gloss than the back side after the simultaneous polishing step but before finish polishing. Advantageously, the method of processing the wafer W is free of any step performed on the back side which is not also performed on the front side. Thus, the wafer W has the flatness and parallelism enabled by simultaneous double-side polishing, has a high gloss mirror finish on the front side due to the finish polishing step, and the method does not require an additional step to be performed on the back side to make the front side distinguishable from the back side. Moreover, the process is more economical in that less material removal from the front side is required in the simultaneous double side polishing step due to the further material removal performed in the finish polishing step.

### EXAMPLE

Simultaneous double-side polishing was performed on 27 test wafers using an AC1200 polisher. The upper pad was a Suba H2 IIE rough polishing pad and the bottom pad was a UR-100 finish polishing pad. The upper platen was rotated at 10 RPM (clockwise), the lower platen was rotated at −10 RPM (counter-clockwise) and the inner and outer pin rings were not rotated so that the rotational speed of the carrier was not manipulated. The polishing slurry was a mixture of KOH and Syton HT-50. The wafers were polished for about 10 minutes, and the gloss of the front and back surfaces was measured using the Mirror-Tri-Gloss at a 60° angle. The gloss data for the test wafers is shown below in Table 2. Wafers 1-12 were etched prior to polishing using NaOH and wafers 13-27 were etched prior to polishing using KOH. As can be seen from the gloss data, there was a substantial difference in gloss between the front surface and back surface of each of the test wafers. It has been found that if the gloss of the back surface is substantially less than about 300 g.u., and if the gloss of the front surface measures at least about 10 g.u. greater than that of the front surface, the gloss difference will allow the front surface and back surface to be easily distinguished by the unaided human eye. In this test, the gloss of each back surface is substantially less than about 300 g.u. and the gloss difference between each front and back surface is at least about 100 g.u. Accordingly, the front surface of each test wafer was easily visually distinguished from the back surface by the unaided human eye.

TABLE 2

| Wafer | Front | Back |
|---|---|---|
| # | Side | Side |
| (NaOH) | Gloss | Gloss |
| 1 | 346 | 241 |
| 2 | 352 | 242 |
| 3 | 355 | 246 |
| 4 | 347 | 244 |
| 5 | 345 | 230 |
| 6 | 330 | 231 |
| 7 | 354 | 250 |
| 8 | 353 | 251 |
| 9 | 337 | 210 |
| 10 | 339 | 223 |
| 11 | 354 | 252 |
| 12 | 323 | 186 |
| 13 | 300 | 123 |
| 14 | 302 | 122 |
| 15 | 295 | 122 |
| 16 | 310 | 125 |
| 17 | 315 | 128 |
| 18 | 303 | 123 |
| 19 | 325 | 129 |
| 20 | 295 | 121 |
| 21 | 312 | 120 |
| 22 | 298 | 112 |
| 23 | 301 | 130 |
| 24 | 317 | 135 |
| 25 | 302 | 125 |
| 26 | 299 | 117 |
| 27 | 297 | 121 |

In view of the above, it will be seen that the several objects of the invention are achieved and other advantageous results attained.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

What is claimed is:

1. A method of polishing front and back surfaces of a semiconductor wafer comprising the steps of:
(a) providing a polishing apparatus having a wafer carrier generally disposed between a first polishing pad and a second polishing pad, said first pad having a hardness significantly greater than a hardness of said second pad,
(b) placing said wafer in the wafer carrier so that said front surface faces said first pad and so that said back surface faces said second pad,
(c) applying a polishing slurry to at least one of said pads,
(d) rotating the carrier, first pad and second pad,
(e) bringing said front surface into contact with said first pad and said back surface into contact with said second pad for simultaneously polishing said front and back surfaces of said wafer, whereby less wafer material is removed from said back surface engaged by said second pad and said back surface has less gloss than said front surface after polishing so that the front surface and back surface are visually distinguishable; and
(f) thereafter finish polishing the front surface of the wafer to reduce haze and roughness in the front surface, the front surface thereby having a higher gloss than the back surface so that the front surface and back surface are visually distinguishable.

2. A method as set forth in claim 1 wherein the first pad is made of polyurethane impregnated polyester felt material and the second pad is made of poromeric polyurethane material.

3. A method as set forth in claim 1 wherein the first pad has a roughness significantly greater than the second pad.

4. A method as set forth in claim 1 wherein a gloss difference between the front surface and back surface after simultaneous polishing is at least about 100 gloss units.

5. A method as set forth in claim 1 wherein the simultaneous polishing is performed for no more than about 10 minutes.

6. A method as set forth in claim 5 wherein the simultaneous polishing removes less than about 3 microns of wafer material from the back surface.

7. A method as set forth in claim 1 wherein the step of rotating includes selecting the relative rotational speed of the carrier, the first pad and the second pad such that removal of material from said back surface of the wafer is minimized.

8. A method as set forth in claim 1 further comprising the step of controlling the temperatures of the first and second pads such that the temperature of the first pad is significantly greater than the temperature of the second pad for removing more material from the front surface of the wafer than the back surface.

9. A method as set forth in claim 1 wherein the first pad removes at least 5 times more wafer material per rotation of the first pad than the second pad.

10. A method of processing a semiconductor wafer sliced from a single-crystal ingot and having front and back surfaces, the method comprising the steps, in order, of:
(a) lapping the front and back surfaces of the wafer to reduce the thickness of the wafer and to improve the flatness of the wafer, the lapping step creating damage on the front and back surfaces;
(b) etching the front and back surfaces of the wafer to reduce the damage on the front surface remaining after the lapping step;
(c) simultaneously polishing the front and back surfaces of the wafer to improve the flatness of the wafer and to reduce wafer damage on the front and back surfaces, the wafer damage remaining on the back surface being greater than the wafer damage on the front surface after completion of said simultaneous polishing step so that said back surface is visually distinguishable from the front surface; and
(d) polishing only the front surface of the wafer to reduce haze and roughness in the front surface, the front surface thereafter having a higher gloss than the back surface, wherein the method is free of any step performed on the back surface which is not also performed on the front surface.

11. A method as set forth in claim 10 wherein the simultaneous polishing is performed for no more than about 10 minutes.

12. A method as set forth in claim 11 wherein the simultaneous polishing removes less than about 3 microns of wafer material from the back surface.

13. A method as set forth in claim 11 wherein a gloss difference between the front surface and back surface after simultaneous polishing is at least about 100 gloss units.

14. The method set forth in claim 10 wherein the step of simultaneously polishing the front and back surfaces comprises:
(a) providing a polishing apparatus having a wafer carrier generally disposed between a first polishing pad and a second polishing pad,
(b) placing said wafer in the wafer carrier so that said front surface faces said first pad and so that said back surface faces said second pad,
(c) applying a polishing slurry to at least one of said pads,
(d) rotating the carrier, first pad and second pad,
(e) bringing said front surface into contact with said first pad and said back surface into contact with said second pad for polishing said front and back surfaces of said wafer simultaneously, said first pad having a hardness significantly greater than a hardness of said second pad whereby less wafer material is removed from said back surface engaged by said second pad, and said front surface has a higher gloss than said back surface after simultaneous polishing.

15. A method as set forth in claim 14 wherein the first pad is made of a felt having polyester therein and the second pad is made of polyurethane material.

16. A method as set forth in claim 15 wherein the first pad is made of polyurethane impregnated polyester felt material and the second pad is made of poromeric polyurethane material.

17. A method as set forth in claim 16 wherein the first pad has a roughness significantly greater than the second pad.

18. The method set forth in claim 14 wherein the etching step is a caustic etching step which inhibits damage to the nanotopography on said back surface.

19. The method set forth in claim 18 wherein the front surface polishing step includes wax mounting the wafer and thereafter polishing the front surface.

20. A method of polishing front and back surfaces of a semiconductor wafer comprising the steps of:
(a) providing a polishing apparatus having a wafer carrier generally disposed between a first polishing pad and a second polishing pad, said first pad having a hardness significantly greater than a hardness of said second pad,
(b) placing said wafer in the wafer carrier so that said front surface faces said first pad and so that said back surface faces said second pad,
(c) applying a polishing slurry to at least one of said pads,
(d) rotating the carrier, first pad and second pad,
(e) bringing said front surface into contact with said first pad and said back surface into contact with said second pad for simultaneously polishing said front and back surfaces of said wafer for no more than about 10 minutes, whereby less wafer material is removed from said back surface engaged by said second pad and a gloss difference between the front and back surfaces is at least about 10 gloss units as measured by a gloss meter after polishing so that the front surface and back surface are visually distinguishable; and
(f) thereafter finish polishing the front surface of the wafer to reduce haze and roughness in the front surface, the front surface thereby having a higher gloss than the back surface so that the front surface and back surface are visually distinguishable.
